(19) United States
(12) Patent Application Publication
(10) Pub. No.: US 2016/0364202 A1
(43) Pub. Date: Dec. 15, 2016

(54) APPARATUS FOR OUTPUTTING AUDIO, DRIVING METHOD OF APPARATUS FOR OUTPUTTING AUDIO, AND NON-TRANSITORY COMPUTER READABLE RECORDING MEDIUM

(71) Applicant: SAMSUNG ELECTRONICS CO., LTD., Suwon-si (KR)

(72) Inventors: Jin-woo RO, Seoul (KR); Won-hee LEE, Seoul (KR); Jean-Christophe NAOUR, Seoul (KR)

(73) Assignee: SAMSUNG ELECTRONICS CO., LTD., Suwon-si (KR)

(21) Appl. No.: 15/144,937

(22) Filed: May 3, 2016

Related U.S. Application Data
(60) Provisional application No. 62/175,629, filed on Jun. 15, 2015.

(30) Foreign Application Priority Data
Sep. 3, 2015 (KR) 10-2015-0125133

(51) Int. Cl. G06F 3/16; H04R 3/00; H03G 3/02

(52) U.S. Cl. CPC G06F 3/162; H03G 3/02; H04R 3/00

(57) ABSTRACT

An audio outputting apparatus having a wheel is provided. The audio outputting apparatus includes a user interface of a wheel format configured to sense a touch gesture and an audio function processor configured to change a predetermined function of the wheel in response to a touch gesture being sensed on an area on the wheel.

### CROSS-REFERENCE TO RELATED APPLICATIONS

This application claims priority from Korean Patent Application No. 10-2015-0125133, filed on Sep. 3, 2015, in the Korean Intellectual Property Office, and claims the benefit of U.S. Provisional Patent Application No. 62/175,629, filed on Jun. 15, 2015, in the United States Patent and Trademark Office, the disclosures of which are incorporated herein by reference in their entireties.

### BACKGROUND

Field of the Invention

Apparatuses and methods consistent with exemplary embodiments relate to an audio outputting apparatus and a method for driving the audio outputting apparatus, and more particularly, to an audio outputting apparatus capable of performing various functions through a touch made on a predetermined area of a wheel (or jog dial) or on a control button, and a method for driving the audio outputting apparatus.

Description of the Related Art

Functions of a conventional jog wheel in a speaker configured to play media contents include increasing and/or reducing the volume of a speaker and adjusting the radio frequency of radios FM/AM. Other functions may be performed by pressing buttons other than the jog wheel.

Adjusting the volume using a jog wheel is a method that is intuitive, natural and has been conventionally used for a long time. However, when adjusting the volume without its state being displayed, it is difficult to know the exact state of the volume. Thus, the exact state of the volume is assumed based on how much the jog wheel was turned.

Furthermore, because speakers have more and more functions for playing media contents in a digital apparatus, various buttons are required to perform those functions. Functions of a speaker typically correlate with the more provided, thereby making it more complicated for a user to manipulate the speaker to play media contents.

### SUMMARY

Exemplary embodiments of the present disclosure provide an audio outputting apparatus capable of performing various functions through a touch made on a predetermined area of a jog wheel or on a control button and a method for driving the audio outputting apparatus.

According to an aspect of an exemplary embodiment of the present disclosure, there is provided a method for driving an audio outputting apparatus having a jog wheel, the method including sensing a touch gesture on an area on the jog wheel for sensing a touch gesture; and changing a function of the jog wheel based on the area in response to the sensed touch gesture.

The sensing may involve sensing the number of times the touch gesture was made on the area, and the time duration the touch was maintained.

The method may further include storing operation information corresponding to the touch gesture, wherein the changing may include changing the function based on the stored operation information corresponding to the touch gesture.

The method may further include, in response to changing the function, displaying information on the changed function on a display located in the center of the jog wheel.

The function of the jog wheel may include at least one of a function of adjusting audio volume, a function of changing contents, a function of changing a communication method of receiving contents, a stand-by function, and a function of outputting audio using peripheral devices.

The method may further include, in response to the jog wheel being manipulated after the function of the jog wheel has been changed, performing operations of the changed function.

The method may further include, in response to receiving an input of a user command of selecting a media apparatus as a source, receiving audio contents from the media apparatus; and outputting the received audio contents as audio.

The receiving audio contents may include reading audio contents recorded in a recording medium inserted into the audio outputting apparatus.

The method may further include changing the function of the jog wheel in response to a control button distanced from the jog wheel being selected.

The method may further include performing the function of the jog wheel in response to a user touch gesture being sensed from an area other than the predetermined area.

The method may further include, in response to a touch gesture being sensed on the jog wheel, performing an event corresponding to the jog wheel and the touch gesture.

According to an aspect of an exemplary embodiment of the present disclosure, there is provided an audio outputting apparatus having a jog wheel having an area on which a touch gesture is sensed; a sensor configured to sense the touch gesture; and an audio function processor configured to change a function of the jog wheel based on the area in response to a touch gesture being sensed on a predetermined area on the jog wheel.

The user interface may sense the number of times the touch gesture was made on the area, and the time duration the touch was maintained.

The apparatus may further include a storage configured to store operation information corresponding to the touch gesture. wherein the audio function processor may change the function based on the stored operation information corresponding to the touch gesture.

The apparatus may further include a display configured to, in response to changing the function, display information on the changed function on the display located in the center of the jog wheel.

The predetermined function of the jog wheel may include at least one of a function of adjusting audio volume, a function of changing contents, a function of changing a communication method of receiving contents, a stand-by function, and a function of outputting audio using peripheral devices.

The audio function processor, in response to the jog wheel being manipulated after the function of the jog wheel has been changed, may perform operations of the changed function.

The apparatus may further include a content receiver configured to, in response to receiving an input of selecting a media apparatus as a source, receive audio contents from the media apparatus; and a sound generator configured to output the received audio contents as audio.

The content receiver may receive audio contents recorded in a recording medium inserted into the audio outputting apparatus.

The audio function processor may change the function of the jog wheel in response to a control button distanced from the jog wheel being selected.

The audio function processor may perform the unction of the jog wheel in response to a user touch gesture being sensed from an area other than the predetermined area.

In response to a touch gesture being sensed on the jog wheel, the audio function processor may perform an event corresponding to the jog wheel and the touch gesture in response to a touch gesture being sensed on the jog wheel.

According to an aspect of an exemplary embodiment of the present disclosure, there is provided a non-transitory computer readable recording medium having a program for executing a method for driving an audio outputting apparatus provided with a jog wheel, the method for driving an audio outputting apparatus including sensing a touch gesture on an area on the jog wheel for sensing a touch gesture; and changing a function of the jog wheel based on the area in response to the sensed touch gesture.

### BRIEF DESCRIPTION OF THE DRAWING FIGURES

The above and/or other aspects of the present disclosure will be more apparent by describing certain exemplary embodiments of the present disclosure with reference to the accompanying drawings, in which:

FIG. 1 is a diagram illustrating an audio outputting system according to an exemplary embodiment;

FIG. 2 is an exemplary diagram of the exterior of an audio outputting apparatus according to an exemplary embodiment;

FIG. 3 is an exemplary block diagram of a driver of an audio outputting apparatus;

FIG. 4 is an exemplary block diagram illustrating a structure of the audio function processor of FIG. 3;

FIG. 5 is an exemplary block diagram of the controller of FIG. 4;

FIGS. 6 and 7 are diagrams for explaining various functions and operations of an audio outputting apparatus according to an exemplary embodiment;

FIGS. 8 to 12 are diagrams illustrating in detail a certain mode in FIG. 8;

FIG. 13 is an exemplary diagram of a process of setting a certain operation through a UI screen in a group mode of FIG. 8;

FIG. 14 is a flowchart illustrating a process of driving an audio outputting apparatus according to an exemplary embodiment;

FIG. 15 is a flowchart illustrating a process of setting a function of an audio outputting apparatus according to an exemplary embodiment; and

FIG. 16 is a view illustrating a process of driving an audio outputting apparatus according to an exemplary embodiment.

### DETAILED DESCRIPTION OF THE EXEMPLARY EMBODIMENTS

Certain exemplary embodiments of the present disclosure will now be described in greater detail with reference to the accompanying drawings.

In the following description, same drawing reference numerals are used for the same elements even in different drawings. The matters defined in the description, such as detailed construction and elements, are provided to assist in a comprehensive understanding of the invention. Thus, it is apparent that the exemplary embodiments of the present an exemplary embodiment can be carried out without those specifically defined matters. Also, well-known functions or constructions are not described in detail since they would obscure this disclosure with unnecessary detail.

Hereinafter, embodiments of the present disclosure will be explained in detail with reference to the drawings attached.

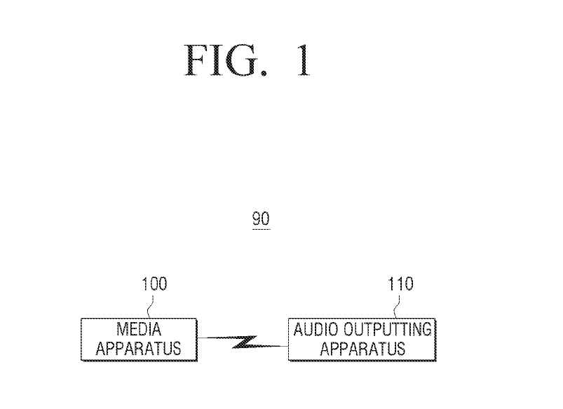

FIG. 1 is a diagram illustrating an audio outputting system according to an exemplary embodiment.

As illustrated in FIG. 1, an audio outputting system 90 according to an exemplary embodiment includes a portion or an entirety of a media apparatus 100 and an audio outputting apparatus 110.

Herein, the phrase “including a portion or an entirety of the aforementioned components” means that the audio outputting apparatus 110 may operate independently in a stand alone manner. However, in the following disclosure, it is assumed that all the aforementioned components are included in the audio outputting system 90.

The media apparatus 100 (or source) include various apparatuses, such as an audio apparatus, television (TV), mobile phone, computer, media player 3 (MP3), programmed data provider (PDP), tablet personal computer (PC), and compact disk (CD) that provide audio contents (or sound source) as media contents. Herein, audio contents may include audio data associated with video data. Such a media apparatus 100 processes audio contents in association with the audio outputting apparatus 110. For example, the media apparatus 100 may provide audio contents to a user through the audio outputting apparatus 110 connected to an external device.

In order to perform such an operation, the media apparatus 100 may include an application (hereinafter referred to as app) for an synchronized operation with the audio outputting apparatus 110. For example, in response to a user selecting a menu icon displayed on a main screen, an app may be executed and thus the audio outputting apparatus 110 may be automatically accessed to process audio contents. For example, in a case where the audio outputting apparatus 110 is set to transmit audio contents through wireless communication, such as Bluetooth or Wi-Fi, the audio contents may be processed through that wireless communication.

In the drawings, a wireless method is exemplified for easy understanding, but this is not a limitation. In an actual implementation, the audio contents may be processed in a wired manner, such as by using a USB or AUX cable. Furthermore, in the above illustration, an app is executed to process the audio contents. However, this is not an limitation of the present disclosure. Instead, the media apparatus 100 may display a menu list on the screen in response to a user's request so that the audio contents may be processed, for example, by the user selecting the audio outputting apparatus 110 from the various items on the list.

The media apparatus 100 according to an exemplary embodiment may perform a function (or operation mode) selected in the audio outputting apparatus 100. For example, assuming that a user changed the audio contents currently being played by the audio outputting apparatus 110, that is, for example, if the user selects a previous song or a next song of the audio contents currently being played by the audio outputting apparatus 110, the audio outputting apparatus 110 may provide the changed audio contents according to the request.

The audio outputting apparatus 110 may operate with prevailing power 220V received from an external power supply, but it may instead operate with DC power provided by an internal battery.

The audio outputting apparatus 110 performs the basic functions of a speaker and includes a sound generator. Furthermore, in a case that audio contents from the media apparatus 100 are processed upon a user's request, the audio outputting apparatus 110 may process the audio contents of the media apparatus 100 according to a default mode and provide the processed audio contents to the user.

As such, in a case that outputting audio contents is set as a default mode, it may be regarded that the audio outputting apparatus 110 is configured to perform a volume adjusting function (or volume mode) according to an exemplary embodiment. In other words, the user may adjust the volume by rotating a jog wheel provided on the audio outputting apparatus 110 to the left or right.

Furthermore, according to an exemplary embodiment, the audio outputting apparatus 110 includes a control button (or menu button, mode button) for changing, for example, a function of adjusting the volume. As the user selects the control button, the function of the audio outputting apparatus 110 is changed from a function of adjusting the volume to a function of selecting a song (or playing mode). In addition, if the user rotates the jog wheel to the left or right, a previous or next song of the song currently being played is selected. In this embodiment, the control button may be a physical button provided outside of the audio outputting apparatus. Or, the control button may not be a physical button, and instead, the control button may be a predetermined area on the jog wheel in cooperation with a sensor. Hereinafter, the predetermined area on the jog wheel will be referred to as a control button.

As previously mentioned, the audio outputting apparatus 110 changes a function based on a manner that the user manipulates the control button (or a user's touch gesture sensed on the predetermined area). In this embodiment, a manipulation manner may include the number of times of selecting the control button (or the number of times of a touch) or a dwelling time of the selection (or duration of the touch being maintained), or a selecting manner (or touch manner). In this embodiment, a selecting manner include various manners, such as a manner of selecting the control button once and then selecting the control button twice consecutively after a period of time, and a manner of selecting the control button once for 1 second and then selecting the control button for 3 seconds and the like. In this embodiment, the dwelling time may be determined based on the duration the control button is pressed with reference to a threshold value. For example, in a function of selecting a song, as the user selects the control button once again, a conversion may be made to a function of pausing the audio currently being output or to a function of outputting the audio again. When the user manipulates the jog wheel after the conversion, the audio may be paused or be output again. Herein, the manipulating manner may be understood as a touch gesture, and the control button may be understood as the predetermined area on the jog wheel.

It is desirable that the audio outputting apparatus 110 according to an exemplary embodiment performs various functions based on the manipulation manner of the control button. For example, in an exemplary embodiment, a function may be further added by simply updating software in the audio outputting apparatus 110. The update may be performed by replacing or changing the software stored in an EEPROM provided in the audio outputting apparatus 110 through a computer or a separate equipment connected externally. In addition, in a case that the media apparatus 100 is a mobile phone or a computer, the related software may be transmitted in a firmware format so that the software may be updated.

An audio outputting apparatus 110 according to an exemplary embodiment includes a control button and jog wheel as a user interface. Accordingly, the user may select a function (or mode) of the audio outputting apparatus 110 by selecting the control button, and then adjust specific operations of the selected function using the jog wheel. For example, if the user selects the control button to perform the function of adjusting the volume, the user may then adjust the volume by rotating the jog wheel. In this embodiment, a detailed operation of the selected function may be an event. For example, if in a playing mode a touch is made instead of rotating the jog wheel to the left or right, the song currently being played will be paused. This pausing operation is an event.

However, the jog wheel according to an exemplary embodiment may be implemented in different ways. For example, the jog wheel may be implemented as a jog wheel apparatus that is physically rotatable, as a key pad format being displayed on a display, as an up/down button formed outside (or outer circumference) the audio outputting apparatus 110, or as an up/down button (or virtual button) of a key pad format being displayed on a display and the like. Therefore, the aforementioned physical job wheel should be regarded as an example, not a limitation.

In summary, when the user manipulates the jog wheel, a function connected to the subject state will be displayed in a graphic format through the display. And if the user presses the control button, a function connected to the subject state will be displayed in a graphic format through the display. The audio outputting apparatus 110 may activate or deactivate a certain operation using the jog wheel. The audio outputting apparatus 110 may also provide a function of using a control button and jog wheel provided in a speaker for playing media contents to connect the speaker to another speaker (for example, a speaker of a TV playing media contents) via the same access point (AP). When music is played by a speaker for playing media contents, i.e., audio contents, from among the speakers for playing media contents connected through the aforementioned function, all the connected speakers for playing audio contents may play the same music. Assuming that the speaker for playing audio contents that first attempted to establish a connection through the aforementioned function is a master speaker, by adjusting the volume of the master speaker, the volume of all the connected speakers for playing audio contents may be adjusted accordingly. The speaker connected after the master speaker becomes a slave speaker, and by adjusting the volume of a slave speaker, only the volume of that speaker may be adjusted.

As a result of the aforementioned configuration, the audio outputting apparatus 110 becomes capable of performing a function or adjustment freely without having to add a button for each of a variety of functions. Accordingly, even when a function is added by updating the software, it is possible to easily add or change a function without changing the external appearance of the audio outputting apparatus 110.

As a change of state caused by manipulating at least one of the jog wheel and a certain button, such as the control button provided as a graphic on the display, the user may become aware of the change of the manipulation, and accordingly, the user may be able to learn about manipulating the audio outputting apparatus 110.

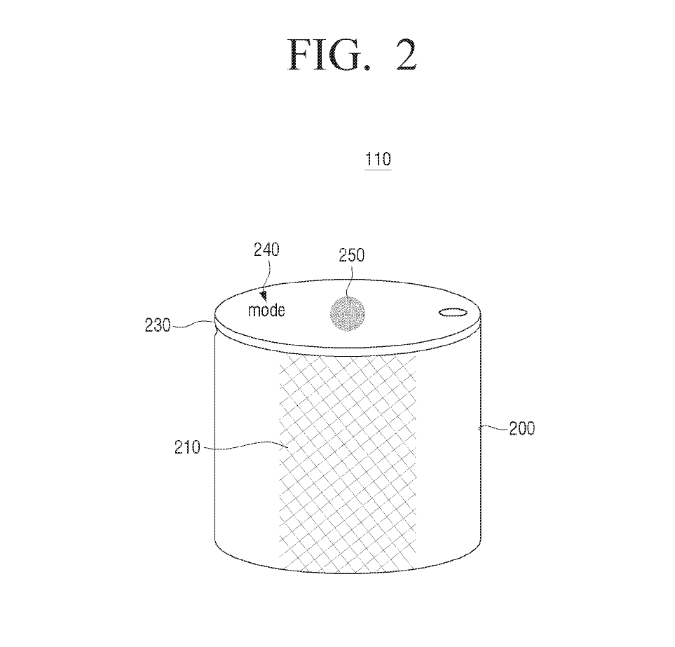

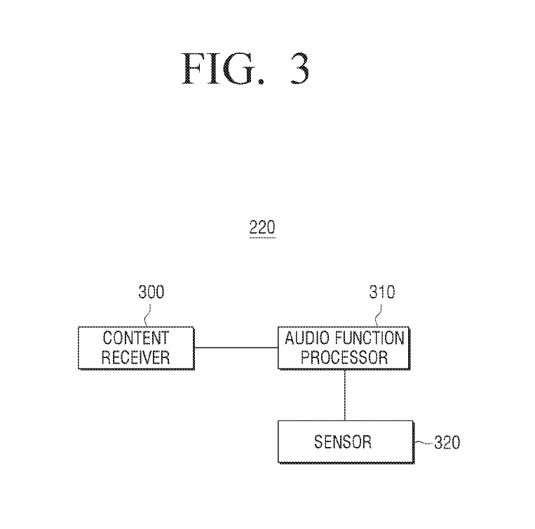

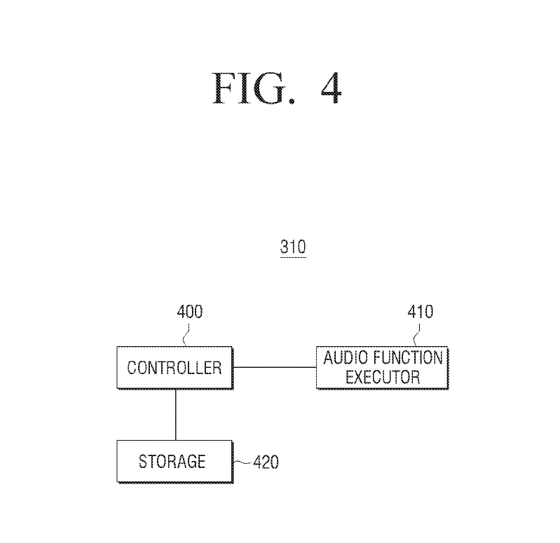

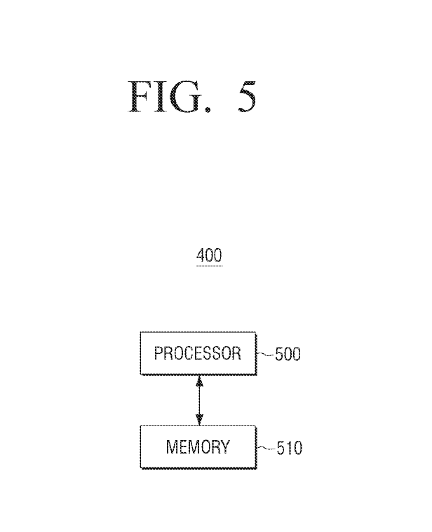

FIG. 2 is an exemplary view of the exterior of an audio outputting apparatus according to an exemplary embodiment, and FIG. 3 is an exemplary view of a driver of the audio outputting apparatus. Furthermore, FIG. 4 is an exemplary block diagram of a structure of an audio function processor of FIG. 3, and FIG. 5 is an exemplary block diagram of a controller of FIG. 4.

As illustrated in FIGS. 2 and 3, an audio outputting apparatus 110 according to an exemplary embodiment includes a portion or an entirety of a main body 200, sound generator 210, driver 220, jog wheel 230, control button 240, and display 250.

Herein, the phrase “including a portion or an entirety of the aforementioned components” means that the audio outputting apparatus 110 may be configured with or without the jog wheel 230. However, in the following disclosure, the audio outputting apparatus 110 may include an entirety of the aforementioned components.

The main body 200 represents an external cover of the audio outputting apparatus 110. On an open front surface of the external cover, the sound generator 210 may be provided. Herein, examples of the sound generator 210 include a speaker.

The driver 220 controls the overall operations inside the audio outputting apparatus 110. For example, the driver 220 may process the received audio contents and output the processed audio contents to the sound generator 210. Furthermore, the driver 220 senses a command (or control signal) sent by the user and displays the state on the display 250 according to the command.

In order to perform the function, as illustrated in FIG. 3, the driver 220 includes a portion or an entirety of a content receiver 330, audio function processor 310, and a sensor 320. Similarly, the phrase “including a portion or an entirety of the aforementioned components” has the same meaning as previously disclosed.

The content receiver 300 may include a wireless communication module, such as Bluetooth or Wi-Fi and the like, to receive media contents from the media apparatus 100 of FIG. 1. Or, the content receiver 300 may receive media contents from a recording medium, such as a compact disk (CD), in which audio contents are recorded. Otherwise, media contents may be received from a USB or mobile phone and the like.

The sensor 320 may sense a user command. For example, the user may input a user command by applying a gesture on a predetermined area of the jog wheel 230 or touching the control button 240. The sensor 320 may sense the gesture/touch and send a signal corresponding to the user command to the audio function processor 310.

The audio function processor 310 processes the received audio contents based on a user command of the user interface and performs various operations related thereto. Herein, various operations refer to those being performed based on the manipulation manner by which the user selected the control button 240. Detailed operations were previously illustrated and thus redundant explanation will be omitted.

The audio function processor 310 according to an exemplary embodiment may have various structures. In other words, it may perform not only the control function realized in a software format, but also all other operations related to functions based on the manipulation manner of the control button 240 and detailed operations of each function.

The audio function processor 310 according to an exemplary embodiment may have a structure as illustrated in FIG. 4. In other words, the audio function processor 310 may include a portion or an entirety of a controller 400, audio function executor 410, and storage 420. Herein, the storage 420 may be omitted.

According to such a configuration, the controller 400 may control the overall operations of the audio outputting apparatus 110 based on a result of execution made in the audio function executor 410. For example, in response to a request from the media apparatus 100 to output certain audio contents, the controller 410 may execute the audio function executor 410 and receive (operation) information for outputting the audio contents, and perform an operation accordingly. For example, because the default method is for outputting audio and adjusting the volume, the controller 400 processes the received audio contents and outputs the processed audio contents to the sound generator 210. Furthermore, the audio outputting apparatus 110 is set to allow a user to adjust volume by adjusting (rotating) the jog wheel 230, and state information related thereto is displayed on the display 250.

In this embodiment, the controller 400 can determine a rotation of the jog wheel 230 as a volume adjustment operation. Therefore, when the user changes a function through the control button 240, the controller 400 changes (or updates) the previously set information to newly designated information.

The storage 420 includes a random access memory (RAM) or a read only memory (ROM). In other words, the storage 420 may temporarily store data being processed in the controller 400. Furthermore, the storage may also store operation information corresponding to the manipulation manner of the control button 240. For example, the operation information may be stored in a RAM, i.e. hardware. Furthermore, storage may also store state information about the function the audio outputting apparatus 110 is currently performing. By checking the stored state information, the controller 400 may determine whether the audio outputting apparatus 110 is currently in a playing mode or a volume adjustment mode.

In addition, the controller 400 may have a structure as illustrated in FIG. 5. Accordingly, the processor 500 inside the controller 400 executes a program which had been stored by the audio function executor 410 at an initial driving of the audio outputting apparatus 110 to a memory 510. Accordingly, when an operation is performed, the program stored in the memory 510 may be executed. Accordingly, the audio outputting apparatus 110 becomes capable of further increasing the data processing speed.

Referring to FIG. 2, the jog wheel 230 is a physically rotatable apparatus and could be incorporated with the control button 240 as a user interface The jog wheel 230 may include or may be synchronized with a plurality of sensors configured to measure a direction, angle or dwelling time and the like of the jog wheel 230. Herein, when the user rotates the jog wheel 230 in a certain direction and then maintains that state for a predetermined time without further rotating the jog wheel, assuming that that operation is an operation of increasing the volume, the audio outputting apparatus 110 will be able to continue to increase the volume based on the dwelling time. The direction may be used to indicate whether to increase or decrease the volume according to the left or right rotation. In addition, the rotation angle may be used to determine which song of the previous or latter songs the user has selected.

More specifically, the jog wheel 230 according to an exemplary embodiment may be rotated by only within a determined angle starting from a reference point. For example, if the reference point is the 12 o'clock direction of a clock, the jog wheel 230 will be rotatable clockwise or counter clockwise, and different operations will be performed according to the direction of the rotation. In other words, in a playing function of selecting a song, if the jog wheel is rotated clockwise, the next song of the currently-played song will be played, and if the jog wheel is rotated counter clockwise, a previous song will be replayed. In another example, with the jog wheel currently being at a state of the function of adjusting the volume, if the jog wheel is rotated clockwise, the volume will increase, and if the jog wheel is rotated counter clockwise, the volume will decrease. Herein, rotation of the wheel may be performed with the user holding or touching the circumference of the jog wheel 230, or through a physically protruding portion or concave portion formed on one area of the jog wheel 230. As previously mentioned, because the jog wheel 230 may be implemented in a variety of forms to adjust the detailed operations of a determined function, the jog wheel 230 is not limited to be implemented in a certain way and there is no limitation of the way to manipulate the jog wheel 230.

In this embodiment, the jog wheel 230 may include a light emitting element, such as an LED. Or, light emitting element may be distanced from the jog wheel 230. The brightness of the light emitting element may be adjusted according to the operation state of the audio outputting apparatus 110 or jog wheel 230, for example, the brightness of the light emitting element may slowly increase as the audio outputting apparatus 110 starts booting and gradually finishes the booting. In an embodiment, this may be done through an animation. For example, the animation may be displayed on the display 250 as a certain pattern, such as water drops becoming gradually bigger or smaller. Otherwise, the animation may be performed as time (or number) being displayed on the display 250. Therefore, there is no particular limitation of the animation operation. For example, if the user touches the jog wheel 230 and changes to a slip state, the brightness of the light emitting element may gradually become dimmer, or a water drop animation may become smaller to show the current state of the audio outputting apparatus 110 or jog wheel 230 to the user.

The control button 240 may include a touch sensor. Therefore, when the control button 240 is selected, the audio outputting apparatus 110 may store information that the user has selected the control button 240 once, and then when the user selects the control button 240 again, the audio outputting apparatus 110 may update the information.

As aforementioned, when the control button 240 is selected, the audio outputting apparatus 110 may store the operation information corresponding to the manipulation manner of the control button 240. In this embodiment, an additional memory may be added to store such information. For example, the operation information may be stored in a registry, and thus there is no particular limitation to the physical configuration of the memory.

The operation information may include binary codes that may be recognized by the driver 220 of the audio outputting apparatus 110. In other words, a binary code is a mechanical language that the audio outputting apparatus 110 can recognize. Therefore, the audio outputting apparatus 110 may perform functions set based on operation information of binary codes. Herein, performing a function that is set based on binary codes may be understood as mode setting. In other words, a mode may be regarded as a regulation that is set by a system designer such that the audio outputting apparatus 110 operates in a predetermined method under certain conditions (ex. manipulation manner). For example, in a case that the system designer sets the audio outputting apparatus 110 to perform a series of operations in a playing mode, if the user selects the control button 240 twice to execute the playing mode, the audio outputting apparatus 110 would perform the series of operation that were set.

The display 250 may be located in the center of the jog wheel. Furthermore, the display 250 displays the function being performed in the audio outputting apparatus 110 and the state of the audio outputting apparatus 110. For example, if the audio outputting apparatus 110 is operating in a playing mode, the display will display that the audio outputting apparatus 110 is in a playing mode, and if the audio outputting apparatus 110 is operating in a volume adjusting mode, the display will display that the audio outputting apparatus 110 is in the volume adjusting mode. Furthermore, if the current volume set in the volume adjusting mode is an intermediate level volume, the display will be able to display that as well in a graphic format.

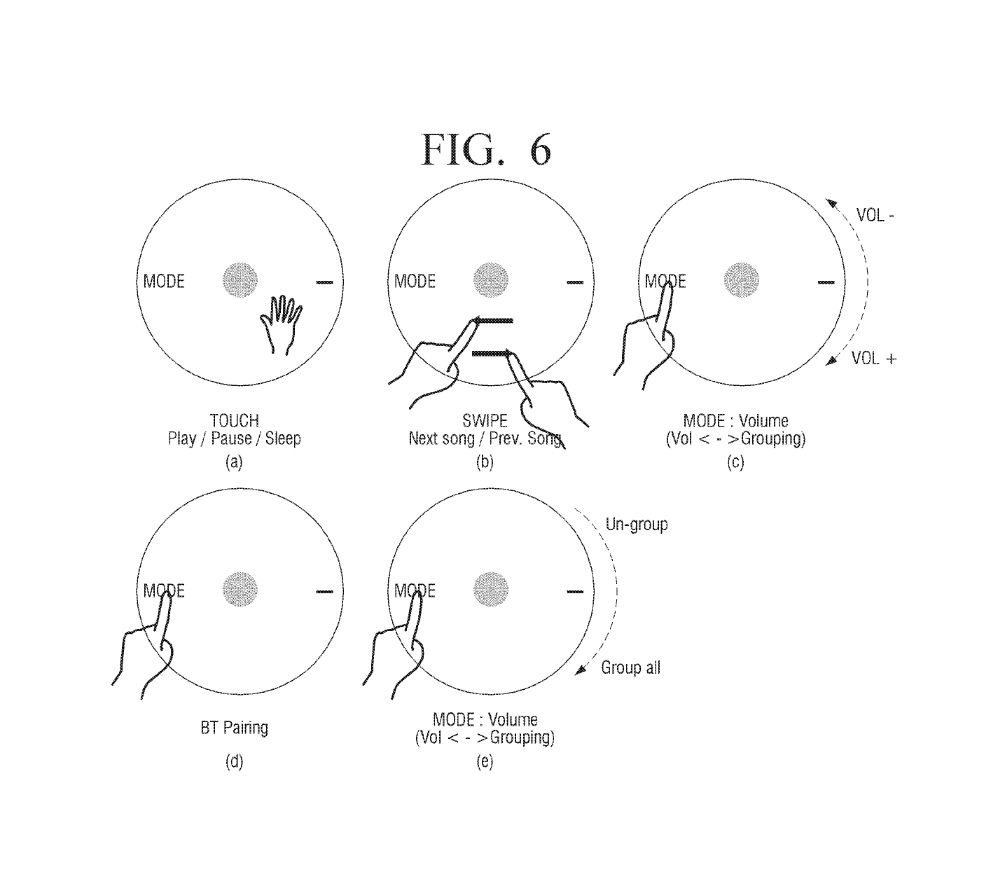

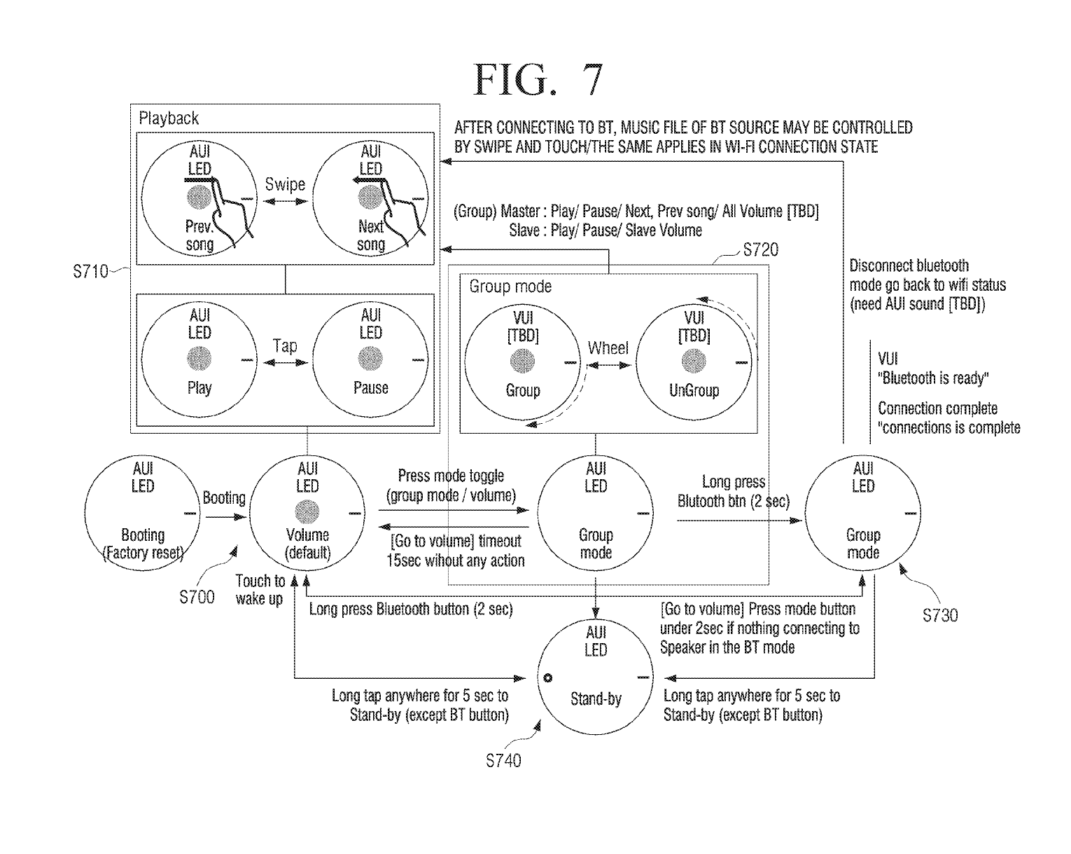

FIGS. 6 and 7 are diagrams for explaining various functions and operations of an audio outputting apparatus according to an exemplary embodiment.

As illustrated in (a) of FIG. 6, the user may perform various operations of play, pause, or sleep by touching the jog wheel 230 of the audio outputting apparatus 110 illustrated in FIG. 2.

Furthermore, as illustrated in (b) of FIG. 6, by a SWIPE operation and not an operation of rotating the jog wheel 230, the audio outputting apparatus 110 may perform an operation of selecting a previous song or a next song while a song is being played.

FIG. 6 (c) to (e) illustrate a case in which a user selects the control button 240 and changes the function of the audio outputting apparatus 110. After selecting the control button 240, the user may rotate the jog wheel 230, thereby controlling detailed operations of a certain function. For example, as illustrated in (c) of FIG. 6, in an audio outputting function, the user may adjust the volume by rotating the jog wheel 230.

More specifically referring to FIG. 7, the audio outputting apparatus 110 according to an exemplary embodiment may determine (or perform) an audio outputting function set as a default mode (S700). In this state, when the user rotates the jog wheel 230, the volume may be adjusted.

If the user selects the control button 240 once, the function of the audio outputting apparatus 110 may be changed to a playing function (S710). With the audio outputting apparatus 110 being set in the playing function, the user may perform an operation of playing or pausing audio by touching the jog wheel 230, and by rotating the jog wheel 230, the user may select a previous song or next song of the song currently being played.

Furthermore, when the user selects the control button 240 once more while the playing function is being performed, the audio outputting apparatus 110 may perform a group mode function (S720). In the group mode, the user may perform an operation of pausing or connecting once again the audio currently being played, but further, when a nearby speaker (a peripheral apparatus) that may output the audio is searched, the user may add the speaker in the group and output the audio. On the other hand, if the peripheral speaker has already been in a group by selecting the group mode, it may be possible to remove the speaker out of the group (stop the connection) by rotating the jog wheel 230.

Furthermore, by performing a long tap (e.g., 2 sec) operation of pressing the control button 240 for a long time while the audio outputting apparatus 110 is in a certain mode, the user may switch the audio outputting apparatus 110 into a Bluetooth mode (S730). Therefore, when the long tap operation of the control button 240 is performed to set the audio outputting apparatus 110 into the Bluetooth mode, the audio outputting apparatus 110 may be disconnected from, for example, a media apparatus 100 and fall into a pairing state again. Furthermore, by rotating the jog wheel 230 in the Bluetooth mode, an operation of connecting to Wi-Fi may be performed. Herein, the detailed operations made by rotating the jog wheel 230 in, for example, a group mode may be an event.

Meanwhile, when the user performs a longer tap (e.g., 5 sec) while he audio outputting apparatus 110 is in a certain mode, the audio outputting apparatus 110 may be switched into a standby mode (S740). Herein, examples of the standby mode include setting the audio outputting apparatus 110 to a waiting mode or to a power saving mode.

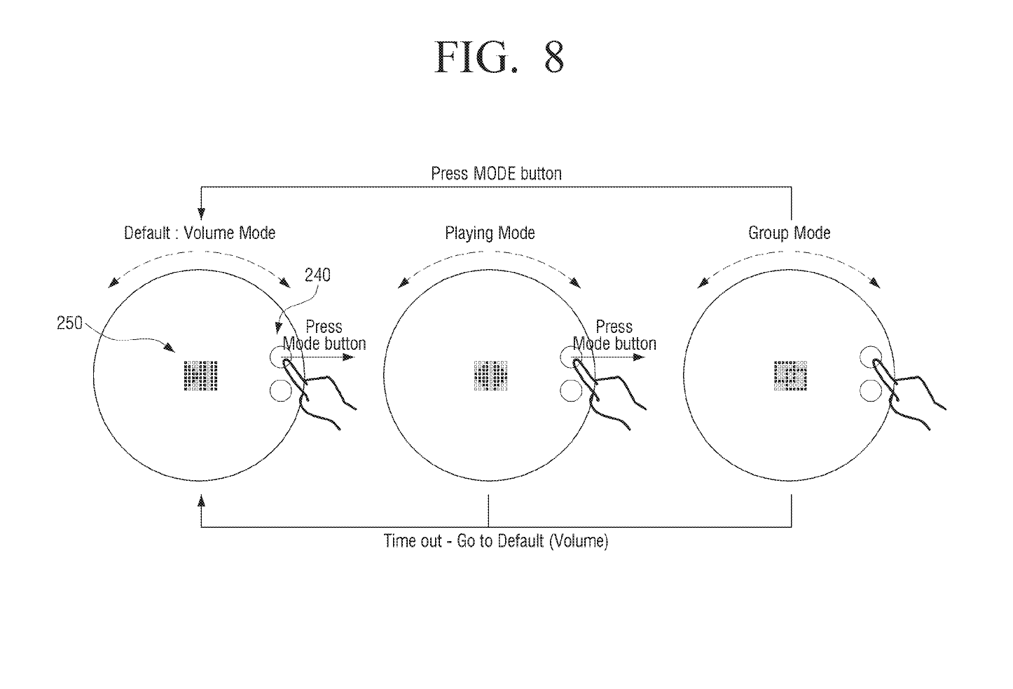

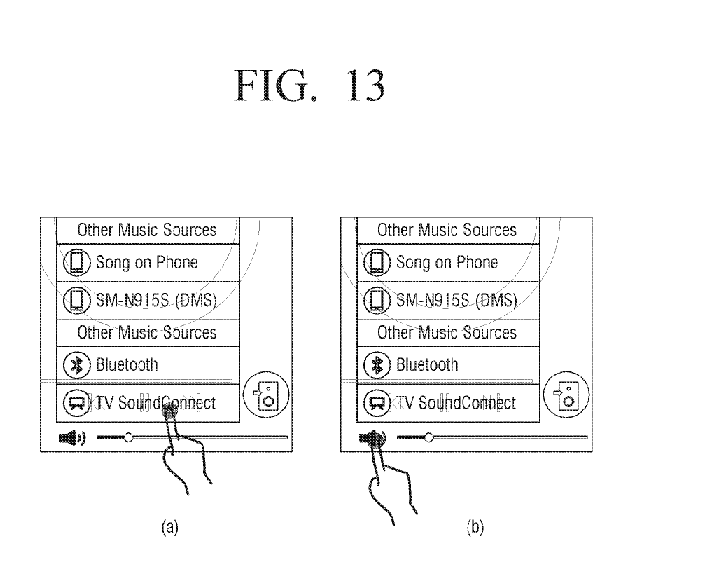

FIGS. 8 to 12 are diagrams illustrating in detail a certain mode of FIG. 8, and FIG. 13 is an exemplary diagram of a process of setting a certain operation through a UI screen in a group mode of FIG. 8;

Referring to FIG. 8 together with FIG. 2, the audio outputting apparatus 110 according to an exemplary embodiment may execute an audio output mode (or volume mode) as a default mode. Herein, the display 250 may display an execution state of the current audio output mode on the screen.

Furthermore, when the control button 240 is selected once again, the function of the audio outputting apparatus 110 is changed to a playing mode, and the situations of that function are displayed on the display 250. After changing the function, the subject function may be performed by rotating the jog wheel 230 to the left or right. For example, in the playing mode, the function is changed from “volume up/down” to “song selection”. Accordingly, the audio outputting apparatus 110 may select a previous song or next song of the song currently being played by rotating (or SWIPE operation) the jog wheel 230.

Furthermore, when the control button 240 is selected once again in the playing mode, the mode of the audio outputting apparatus 110 may be changed to a group mode. For example, in the group mode, it is possible to control the speakers within a specific distance to output audio by manipulating the jog wheel 230. For example, in a case that the speakers within a specific distance are connected by manipulating the jog wheel 230, the audio outputting apparatus 110 may transmit audio contents to other speakers while outputting the audio contents. Accordingly, the other speakers may also output the audio contents and operate as slave devices.

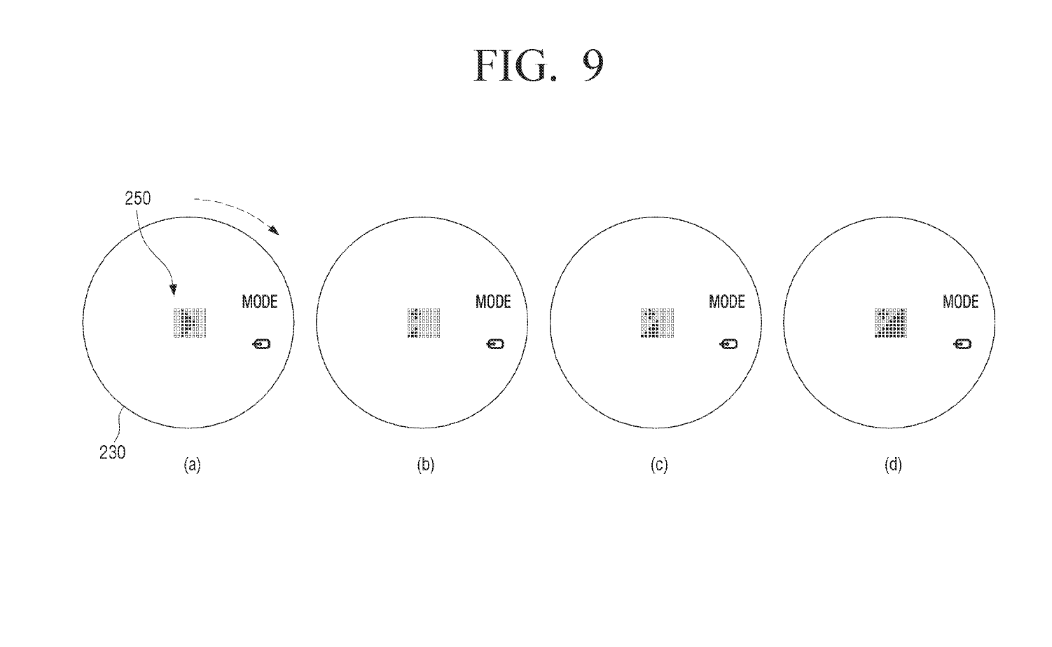

More specifically, in the audio output mode, the audio outputting apparatus 110 may adjust the volume using the jog wheel 230 as illustrated in (a) to (d) of FIG. 9 and may display its current state on the display 250. The volume increases according to the direction (e.g., right) of rotating the jog wheel, and a feedback (e.g., an adjustment value) is displayed on the display 250. The larger the rotation angle of the jog wheel 230, the larger the volume.

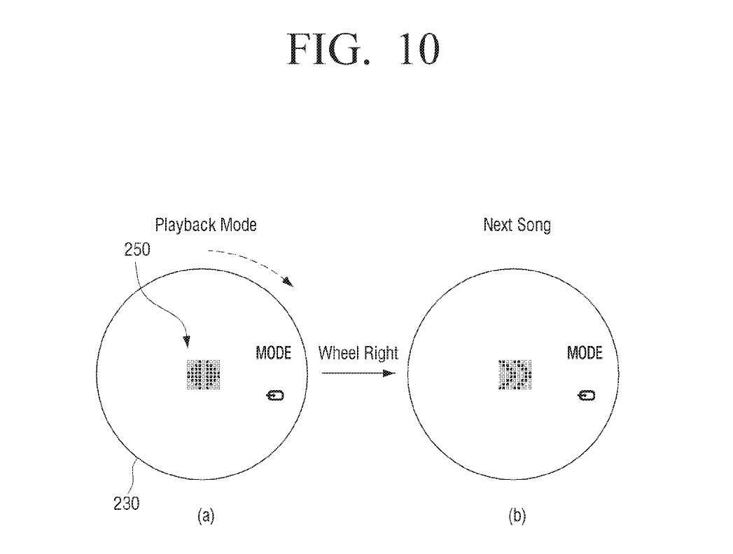

Furthermore, as illustrated in (a) and (b) of FIG. 10, the audio outputting apparatus 110 may change a song using the jog wheel 230 in the playing mode, and display the current state on the display 250. For example, by rotating the jog wheel 230 to the right, it is possible to change to a next song.

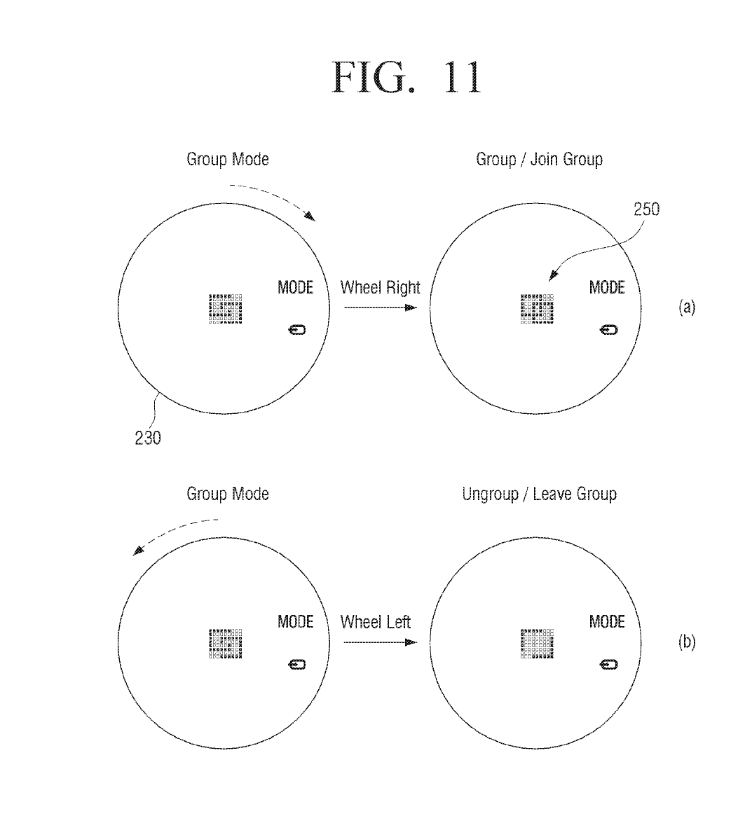

Furthermore, as illustrated in (a) and (b) of FIG. 11, in a case of rotating the jog wheel 230 in a group mode, it is possible to connect or disconnect a speaker for playing audio contents. For example, rotating to the left may relate to connecting the speaker while rotating to the right relates to disconnecting the speaker. Herein, the speaker may be a speaker of a peripheral device located within a specific distance. For example, the speaker could be a speaker of an image display apparatus, such as a TV or computer, close to the audio outputting apparatus 110.

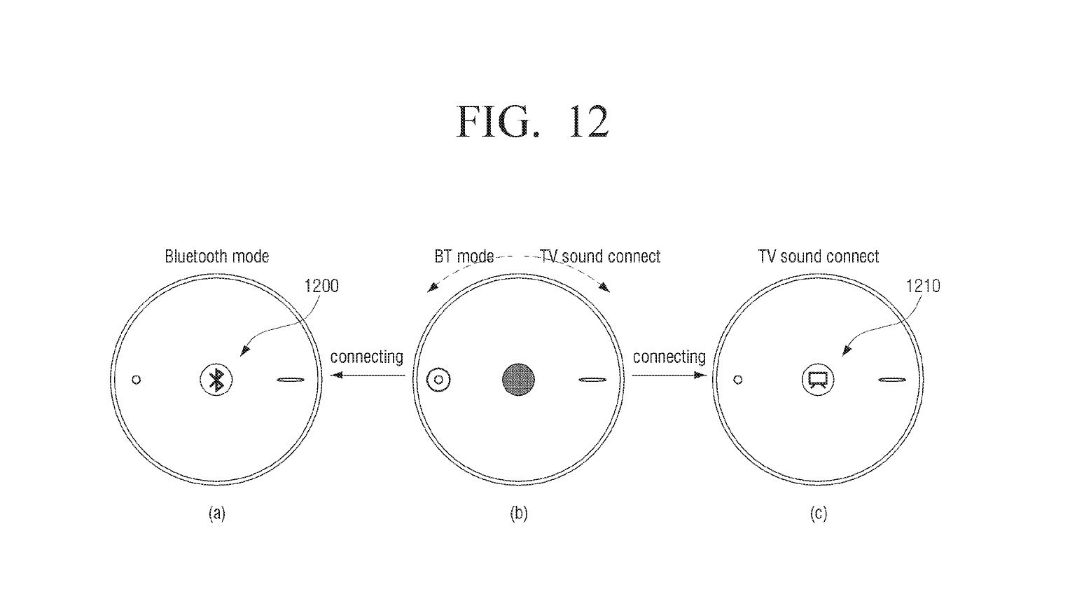

In this embodiment, the audio outputting apparatus 110 may add a new mode as illustrated in FIG. 12. For example, according to an embodiment, by consecutively selecting the control button 240 three times, the mode may be changed as illustrated in (a) of FIG. 12. Accordingly, as illustrated in (b) and (c) of FIG. 12, the audio outputting apparatus 110 may enter into a Bluetooth mode for executing a Bluetooth mode according to a left or right rotation of the jog wheel 230, and display a state thereof 1200, or connect to a nearby TV and enter into a mode for outputting audio and display a state thereof 1210 on the screen.

For example, in the group mode of FIG. 8, the audio outputting apparatus 110 may search a peripheral device, and display a UI screen. In such a case, the user may select an item for TV connection so that audio may be output to the TV. Herein, volume adjustment may be made by selecting a speaker icon as in (b) of FIG. 13. As such, according to an embodiment, it is possible to control detailed operations of a certain function in various methods.

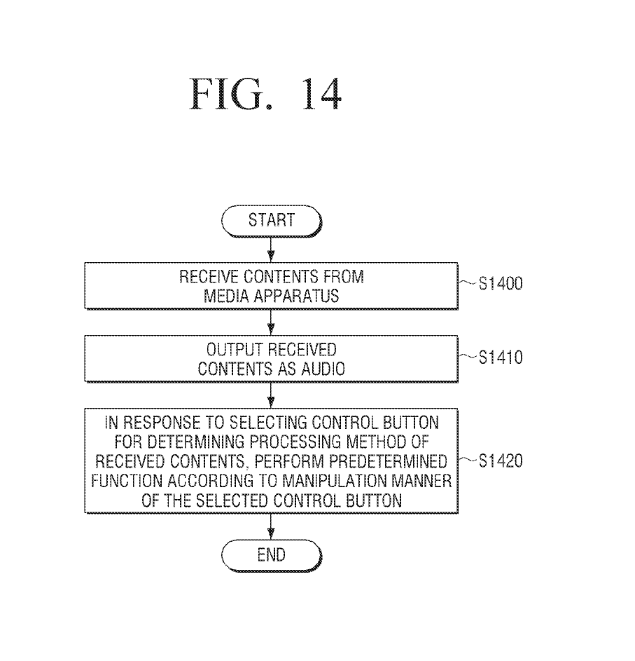

FIG. 14 is a flowchart illustrating a process for driving an audio outputting apparatus according to an exemplary embodiment.

Referring to FIG. 14 and FIG. 1, the audio outputting apparatus 110 receives contents from the media apparatus 100 (S1400). Herein, it is desirable that the media apparatus 100 is a separate apparatus that is independently controllable. In addition, the media apparatus 100 may include a storage medium, such as a CD. Furthermore, it is desirable that the contents are music contents.

Next, the audio outputting apparatus 110 outputs the received contents as audio (S1410). Herein, the contents are audio data, and the audio is sound. In such a case where the audio is output right away, it can be assumed that the audio outputting apparatus 110 had been set into a default mode where volume can be adjusted by for example rotating the jog wheel.

Furthermore, when a control button for determining the method for processing the (received) contents is selected, the audio outputting apparatus 110 performs a predetermined function corresponding to the manipulation manner of the control button (S1420). For example, with the number of times selected, a playing mode or a group mode may be performed, whereas with the dwelling time, a Bluetooth mode and standby mode may be performed. Herein, a mode may represent a function. Furthermore, in order to perform a predetermined function, upon storing the operation information corresponding to the manipulation format, the predetermined function may be performed based on the stored operation information.

Herein, the operation information consists of a mechanical language, such as binary codes.

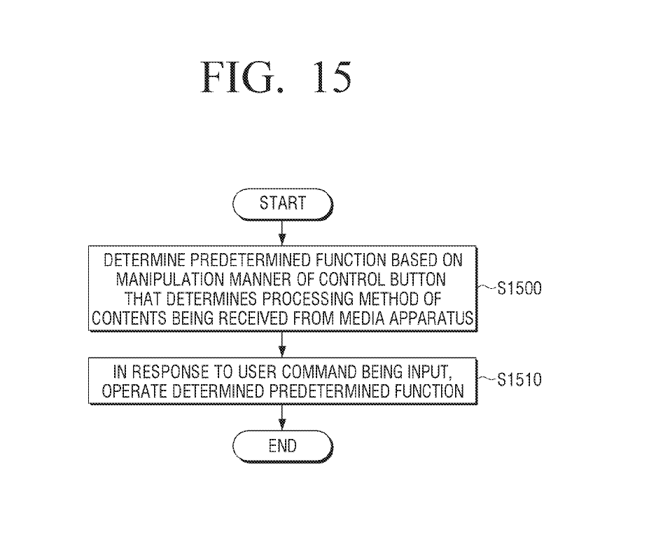

FIG. 15 is a flowchart illustrating a process of performing a function of an audio outputting apparatus according to an exemplary embodiment.

Referring to FIG. 15 and FIG. 1 the audio outputting apparatus 110 determines a predetermined function corresponding to the manipulation manner of the control button for determining the processing method of the contents being received from the media apparatus 100 (S1500). Such a determination operation may include checking whether or not the control button was manipulated, and if so, checking in which manner the control button was manipulated, and then based on that result, determining a predetermined function. In this process, an operation of generating or outputting operation information corresponding to the manipulation manner may be further performed.

Furthermore, when a user command is input, the audio outputting apparatus 110 operates the determined predetermined function (S1510). Herein, the user command is made by manipulating the jog wheel or other buttons and the like, and detailed operations of the determined function may be performed by that jog wheel or other buttons. If the user command was made by voice recognition, voice recognition may well be used.

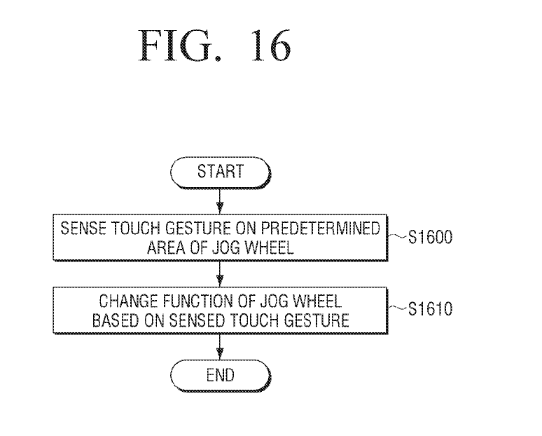

FIG. 16 is a flowchart illustrating a process of driving an audio outputting apparatus according to an exemplary embodiment.

Referring to FIG. 16 and FIG. 1, the audio outputting apparatus 110 senses a touch gesture on a predetermined area of the jog wheel for sensing touch gestures (S1600). Herein, the touch gesture is a manipulation manner applied on the predetermined area, and it may include the number of times selected (or touched) or duration of the touch and the like.

Furthermore, the audio outputting apparatus 110 changes the function of the jog wheel based on the sensed touch gesture (S1610). Herein, functions have been illustrated in the above disclosure and thus further illustration is omitted.

Next, the audio outputting apparatus 110 may perform a detailed operation, that is, an event of the changed function by, for example, rotating the jog wheel. For example, the audio outputting apparatus 110 may perform detailed operations of playing the next song by rotating the jog wheel to the right, or playing the previous song by rotating the jog wheel to the left. Furthermore, the audio outputting apparatus 110 may stop playing a song by touching the top end of the jog wheel.

In the above embodiments, manipulations are made on a control button and a physical jog wheel. However, manipulations could also be made on a key pad realized by software. Furthermore, a jog wheel may be realized as an up/down button, and the up/down button may be physical or realized by software.

In addition, the aforementioned jog wheel may be replaced by voice recognition. For example, when the user says ‘previous song’ with the audio outputting apparatus 110 operated in a playing mode, detailed operations may be performed based on a result of the voice recognition. This may be performed by executing a voice recognition engine (or recognition program) provided in the audio outputting apparatus 110, or it may be performed through an interlocked operation with an external recognition server.

Furthermore, such a voice recognition method may replace not only the jog wheel but also the control button. For example, when the user says ‘volume (mode)’, ‘play (mode)’ or ‘bluetooth (mode)’, the sound may be recognized and a corresponding functional may be executed. Or, the user may simply say ‘one’, ‘two, or ‘three’, and the sound may be recognized and a function corresponding to a specific number may be executed. For example, when the user says ‘play’ and the audio outputting apparatus 110 is set into a playing mode, the user may then say ‘previous song’ to select the previous song.

As such, because a control button or jog wheel may be replaced by a variety of other forms of recognition, there is no particular limitation of the device or function.

Meanwhile, even if it was explained that one of each type of components is included to form the present disclosure, there is no limitation thereto. That is, as long as they are within the scope of t the present disclosure, one or more components may be selected and combined. Furthermore, even if it was explained that each component is realized as one specific hardware structure, a portion or an entirety of the components may be selectively combined to be realized as a computer program having a program module for performing a portion or an entirety of functions combined in one or a plurality of hardware structures. The codes and code segments forming the computer program may be easily implemented by those skilled in the art. Such a computer program may be stored in a non-transitory computer readable recording medium, and then be read and executed by a computer, thereby realizing an embodiment of the present disclosure.

A non-transitory computer readable recording medium refers to a computer readable medium that is capable of storing data semi-permanently unlike a medium that stores data for a short period of time such as a register, cache, and memory. More specifically, the aforementioned programs may be stored in and provided via a non-transitory computer readable medium such as a CD, digital versatile disc (DVD), hard disk, blue ray disc, universal serial bus (USB) stick, memory card and ROM.

The foregoing exemplary embodiments and advantages are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. A method for driving an audio outputting apparatus having a wheel, the method comprising:
sensing a touch gesture on an area on the wheel for sensing a touch gesture; and
changing a function of the wheel based on the area in response to the sensed touch gesture.

2. The method according to claim 1, wherein the sensing comprises sensing the number of times the touch gesture was made on the predetermined area or the time duration the touch gesture was maintained on the area.

3. The method according to claim 1, further comprising:
storing operation information corresponding to the touch gesture,
wherein the changing comprises changing the function based on the stored operation information corresponding to the touch gesture.

4. The method according to claim 1, further comprising:
in response to the changing function, displaying information of the changed function on a display located in a center of the wheel.

5. The method according to claim 1, wherein the function of the wheel comprises at least one of a function of adjusting audio volume, a function of changing contents, a function of changing a communication method of receiving contents, a stand-by function, and a function of outputting audio using peripheral devices.

6. The method according to claim 5, further comprising:
in response to the wheel being manipulated after the function of the wheel has been changed, performing operations of the changed function.

7. The method according to claim 1, further comprising:
in response to receiving an input of a user command of selecting a media apparatus as a source, receiving audio contents from the media apparatus; and
outputting the received audio contents as audio.

8. The method according to claim 7, wherein the receiving audio contents comprises reading audio contents recorded in a recording medium inserted into the audio outputting apparatus.

9. The method according to claim 1, further comprising:
changing the function of the wheel in response to a control button being selected.

10. The method according to claim 1, further comprising:
performing the function of the wheel in response to a user touch gesture being sensed from an area other than the area.

11. The method according to claim 1, further comprising:
in response to a touch gesture being sensed on the wheel, performing an event corresponding to the predetermined wheel and the touch gesture.

12. An audio outputting apparatus, the apparatus comprising:
a wheel having an area on which a touch gesture is sensed; and
an audio function processor configured to change a function of the wheel based on the area in response to the sensed touch gesture.

13. The apparatus according to claim 12, wherein the touch gesture comprises a number of times a touch is applied on the area and a time duration of a touch is applied on the predetermined area.

14. The apparatus according to claim 12, further comprising:
a memory configured to store operation information corresponding to the touch gesture,
wherein the audio function processor changes the function based on the stored operation information corresponding to the area of the touch gesture.

15. The apparatus according to claim 12, further comprising:
a display, located in the center of the wheel, configured to display information of the changed function in response to the function being changed.

16. The apparatus according to claim 12, wherein the function of the wheel comprises at least one of a function of adjusting audio volume, a function of changing contents, a function of changing a communication method of receiving contents, a stand-by function, and a function of outputting audio using peripheral devices.

17. The apparatus according to claim 12, further comprising:
a control button, wherein the audio function processor changes the predetermined function of the wheel in response to the control button being selected.

18. The apparatus according to claim 12, wherein the audio function processor performs the function of the wheel in response to a user touch gesture being sensed from an area other than the area.

19. The apparatus according to claim 12, wherein, in response to a touch gesture being sensed on the wheel, the audio function processor performs an event corresponding to the wheel and the touch gesture in response to a touch gesture being sensed on the wheel.

20. A non-transitory computer readable recording medium having a program for executing a method for driving an audio outputting apparatus provided with a wheel, the method for driving an audio outputting apparatus comprising:
sensing a touch gesture on an area on the wheel for sensing a touch gesture; and
changing a function of the wheel based on the area in response to the sensed touch gesture.
